(19) United States
(12) Patent Application Publication
(10) Pub. No.: US 2025/0304294 A1
(43) Pub. Date: Oct. 2, 2025

(54) CIRCUIT BOARD CONNECTION MECHANISM AND DRONE DEVICE

(71) Applicant: QISDA CORPORATION, Taoyuan City (TW)

(72) Inventors: Cheng-Chih Huang, Taoyuan City (TW); Yi-Ting Lee, Kaohsiung City (TW)

(73) Assignee: QISDA CORPORATION, Taoyuan City (TW)

(21) Appl. No.: 19/014,164

(22) Filed: Jan. 8, 2025

(30) Foreign Application Priority Data
Apr. 1, 2024 (CN) 202410388091.4

(51) Int. Cl. B64U 20/83; B64U 10/10; H05K 1/02

(52) U.S. Cl. CPC B64U 20/80; H05K 1/0277; B64U 10/14; H05K 2201/056; H05K 2201/2045

(57) ABSTRACT

A circuit board connection mechanism is applied to a drone device and includes a base, at least one positioning component, a flexure circuit board and a hard substrate. The positioning component includes a first section, a second section and a third section connected to each other. A width of the second section is smaller than a width of the first section and a width of the third section. The flexure circuit board is disposed on the hard substrate. The hard substrate includes a hole structure and a supporting structure connected to each other. A restraint annular structure of the supporting structure can be attached to the second section. A radial dimension of the restraint annular structure is smaller than the widths of the first section and the third section, and greater than the width of the second section.

### BACKGROUND OF THE INVENTION

### 1. Field of the Invention

The present invention relates to a circuit board connection mechanism and a related drone device, and more particularly, to a circuit board connection mechanism that can prevent the printed circuit board from damage due to violent vibration and a related drone device having the circuit board connection mechanism.

### 2. Description of the Prior Art

With the advanced technology, the drone has changed from the entertainment application to the functional application, and can provide the image collection function more than flight performance. Taking the multi-wing drone as an example, the motor of the multi-wing drone drives the propellers to generate the lift for achieving the vertically takeoff and landing functions. The conventional drone utilizes the high-sensitivity camera module to capture and analyze the image for identifying the obstacle within the surveillance region during the flight; however, the conventional high-sensitivity camera module is fixed with the flexible printed circuit board and the hard printed circuit board, which is easy to shake the flexible printed circuit board when the drone is in the flip flight, and the interface between the flexible printed circuit board and the hard printed circuit board may be broken. Therefore, design of a circuit board connection mechanism and a related drone that can prevent the printed circuit board from damage due to violent vibration is an important issue in the mechanical design industry.

### SUMMARY OF THE INVENTION

The present invention provides a circuit board connection mechanism that can prevent the printed circuit board from damage due to violent vibration and a related drone device having the circuit board connection mechanism for solving above drawbacks.

According to the claimed invention, a circuit board connection mechanism includes a base, at least one positioning component, a flexure circuit board and a hard substrate. The at least one positioning component is disposed on the base. The positioning component includes a first section, a second section and a third section connected to each other. The third section is connected to the base. A second structural width of the second section is smaller than a first structural width of the first section and a third structural width of the third section. The flexure circuit board is disposed on the hard substrate. The hard substrate includes a hole structure and a supporting structure. An end of the supporting structure is connected to a wall of the hole structure. A restraint annular structure formed by the supporting structure is movably attached to the second section. A radial dimension of the restraint annular structure is smaller than the first structural width and the third structural width, and greater than the second structural width.

According to the claimed invention, an outline of the first section of the positioning component is a curved structure, and a segment structure is formed on a boundary between the second section and the third section.

According to the claimed invention, the supporting structure includes a connection portion and a C-type portion, two opposite ends of the connection portion are respectively connected to the C-type portion and the wall of the hole structure.

According to the claimed invention, the supporting structure includes a plurality of arm units arranged in a symmetric manner. Each arm unit includes a connection portion and an arc portion, two opposite ends of the connection portion are respectively connected to an end of the arc portion and the wall of the hole structure, and the other end of the arc portion is adjacent to and spaced from another arm unit.

According to the claimed invention, the circuit board connection mechanism further includes a recovering component disposed between the hard substrate and the base.

According to the claimed invention, a resiliently deformed direction of the recovering component is parallel to a planar normal vector of the hard substrate.

According to the claimed invention, the recovering component is a helical compression spring or a S-type compression spring.

According to the claimed invention, the circuit board connection mechanism further includes a plurality of positioning components, and the recovering component is disposed among the plurality of positioning components.

According to the claimed invention, a drone device includes a case, a rotary wing mechanism, a driving module and a circuit board connection mechanism. The rotary wing mechanism is disposed outside the case. The driving module is electrically connected to the rotary wing mechanism and disposed inside the case. The circuit board connection mechanism is disposed inside the case. The circuit board connection mechanism includes a base, at least one positioning component, a flexure circuit board and a hard substrate. The base is adapted to hold the driving module. The at least one positioning component is disposed on the base. The positioning component includes a first section, a second section and a third section connected to each other. The third section is connected to the base. A second structural width of the second section is smaller than a first structural width of the first section and a third structural width of the third section. The flexure circuit board is disposed on the hard substrate. The hard substrate includes a hole structure and a supporting structure. An end of the supporting structure is connected to a wall of the hole structure. A restraint annular structure formed by the supporting structure is movably attached to the second section. A radial dimension of the restraint annular structure is smaller than the first structural width and the third structural width, and greater than the second structural width.

The flexure circuit board can have a flexible function, and can be bent or folded for assembly, and therefore can meet the lightweight design requirement of the drone device because of light weight and thin thickness of the flexure circuit board. The present invention can provide the circuit board connection mechanism applied to the drone device, which can avoid an unexpected situation of the flexure circuit board, such as breakage or falling off, caused by instantaneous swing of the drone device during the flight. The circuit board connection mechanism of the present invention can utilize the positioning component with a middle section that is narrower than both end sections, and the hard substrate with the supporting structure having the resilient recovering features assembled with the flexure circuit board, to provide multi-axis dynamic adjustment in accordance with changes of the flight angle of the drone device, so as to effectively prevent the flexure circuit board from being damaged when the drone device is violently swung.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a drone device according to an embodiment of the present invention.

FIG. 2 is an assembly diagram of a circuit board connection mechanism according to the embodiment of the present invention.

FIG. 3 is an exploded diagram of parts of the circuit board connection mechanism 18 according to the embodiment of the present invention.

FIG. 4 is an application diagram of a recovering component according to the embodiment of the present invention.

FIG. 5 is a diagram of a positioning component according to the embodiment of the present invention.

FIG. 6 is an assembly diagram of the positioning component and a hard substrate according to the embodiment of the present invention.

FIG. 7 is a diagram of the hard substrate according to another embodiment of the present invention.

### DETAILED DESCRIPTION

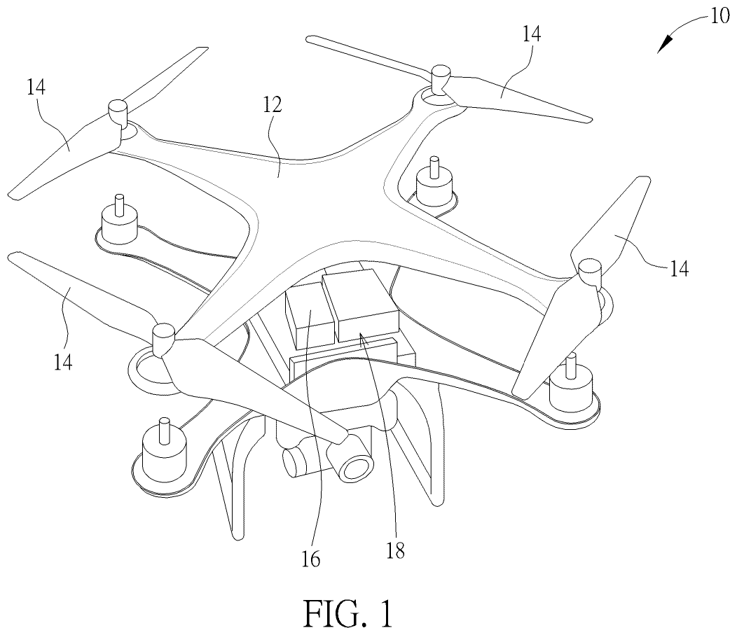

Please refer to FIG. 1. FIG. 1 is a diagram of a drone device 10 according to an embodiment of the present invention. The drone device 10 can be a single-wing drone or a multi-wing drone, and are not limited to the embodiment shown in FIG. 1. The drone device 10 can include a case 12, a rotary wing mechanism 14, a driving module 16 and a circuit board connection mechanism 18. The case 12 can accommodate several electronic controlling components of the drone device 10, such as an infrared sensor, an ultrasonic sensor, an image sensor and a GPS receiver. The rotary wing mechanism 14 can be disposed on the case 12; a type and position of the rotary wing mechanism 14 can depend on a design demand.

The driving module 16 can be disposed inside the case 12, and electrically connected to the rotary wing mechanism 14. In the embodiment, the driving module 16 can be defined as an aircraft flight control system of the drone device 10. The circuit board connection mechanism 18 can be disposed inside the case 12, and used to hold the driving module 16. When the driving module 16 controls the rotary wing mechanism 14 of the drone device 10 for flight, the driving module 16 can cooperate with a shock absorbing element (which is not marked in the figure) to make physical correction, and elements (such as the flexure circuit board) of the circuit board connection mechanism 18 can be shook accordingly; vibration amplitude of the drone device 10 can be slowed down via the circuit board connection mechanism 18 of the present invention, so as to avoid element damage between the driving module 16 and the circuit board connection mechanism 18.

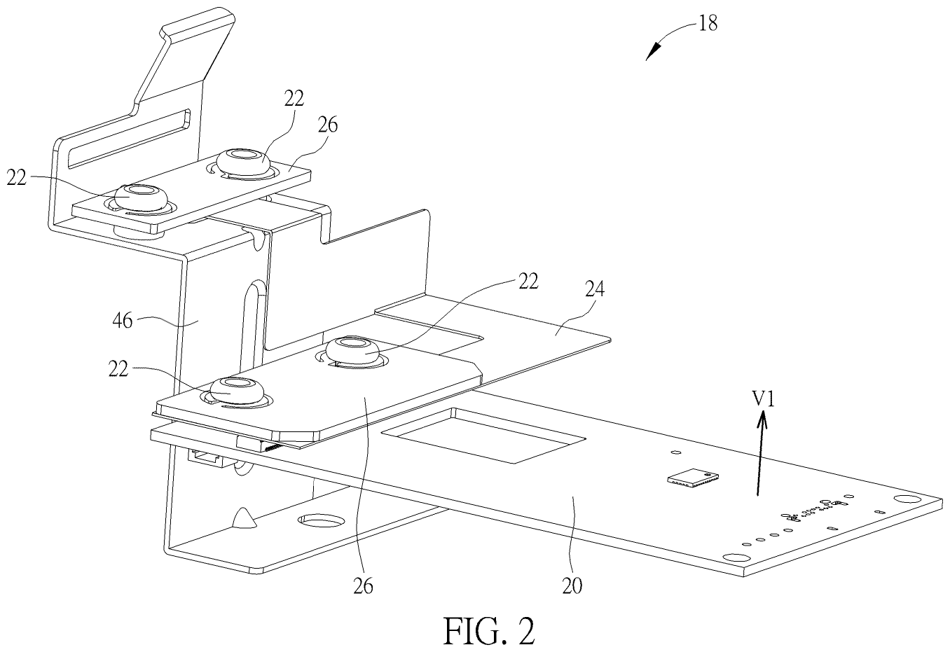

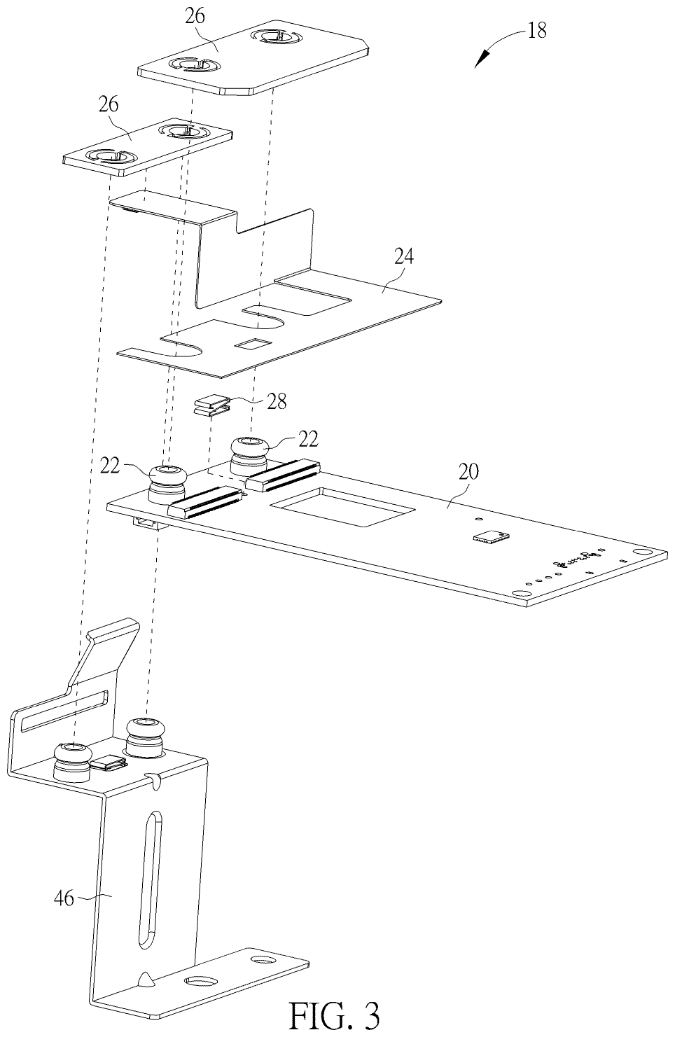

Please refer to FIG. 2 and FIG. 3. FIG. 2 is an assembly diagram of the circuit board connection mechanism 18 according to the embodiment of the present invention. FIG. 3 is an exploded diagram of parts of the circuit board connection mechanism 18 according to the embodiment of the present invention. The circuit board connection mechanism 18 can include a base 20, a positioning component 22, a flexure circuit board 24, a hard substrate 26 and a recovering component 28. The base 20 can be a circuit board or sheet metal, which depends on the design demand of the drone device 10. The driving module 16 can be disposed on the base 20. A number of the positioning component 22 is not limited to the embodiment shown in the figures. The positioning component 22 can pass through the flexure circuit board 24 and the hard substrate 26, and be disposed on the base 20. The positioning component 22 can be used to prevent the flexure circuit board 24 and the hard substrate 26 from being separated from the base 20 for preferred buffer efficiency.

The flexure circuit board 24 can be disposed on the hard substrate 26 via the positioning component 22, and be located between the base 20 and the hard substrate 26. The hard substrate 26 can be a circuit board or an iron element, which depends on the design demand of the drone device 10. Connection between the positioning component 22, the flexure circuit board 24 and the hard substrate 26 can utilize an adjustable flexible function of the hard substrate 26 to provide dynamic correction by the circuit board connection mechanism 18 in response to the flight of the drone device 10, so as to prevent junction between the flexure circuit board 24 and the positioning component 22 or the hard substrate 26 from being damaged.

In addition, the recovering component 28 can be disposed between the base 20 and the hard substrate 26. A resiliently deformed direction of the recovering component 28 can be perpendicular to an upper surface of the hard substrate 26, which means the resiliently deformed direction of the recovering component 28 can be substantially parallel to a planar normal vector V1 of the hard substrate 26. In the embodiment of the present invention, the recovering component 28 can be preferably designed as a S-type compression spring, which can keep contact between the recovering component 28 and the base 20 and the flexure circuit board 24 via the flight movement inertia and the resilient recovering force in response to the flight of the drone device 10, so that the circuit board connection mechanism 18 can provide the dynamic correction when the flight angle of the drone device 10 is changed. The recovering component 28 can be designed as the spring with other types, such as a helical compression spring, and the practical application of the recovering component 28 can depend on an actual demand.

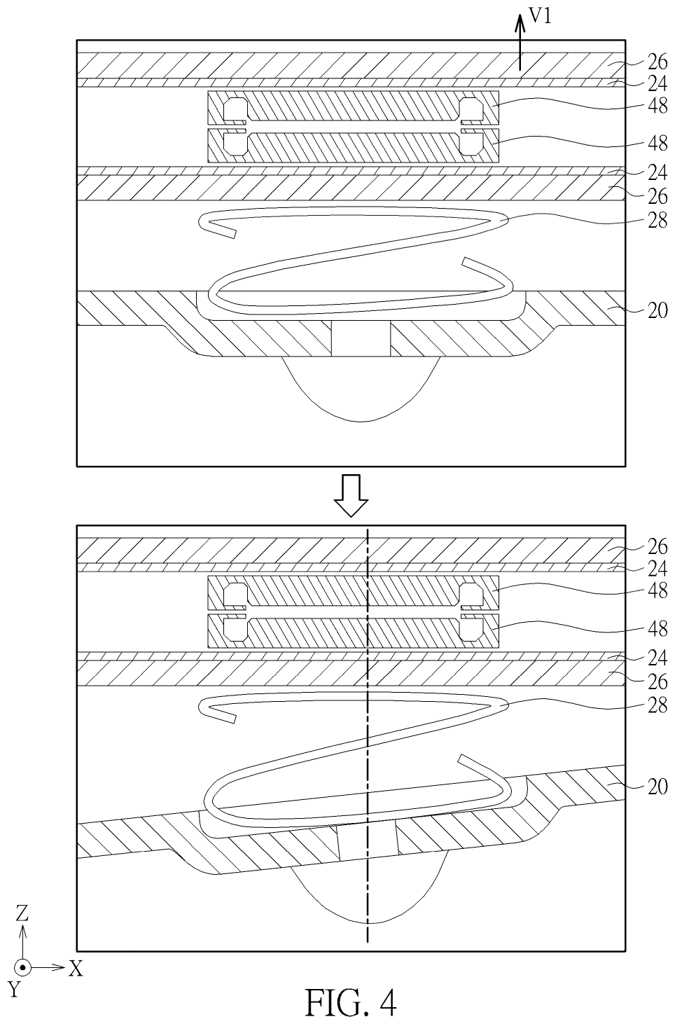

Please refer to FIG. 4. FIG. 4 is an application diagram of the recovering component 28 according to the embodiment of the present invention. When the drone device 10 is rapidly tilted or rotated in the flight, the driving module 16 can provide the dynamic correction which may cause the circuit board connection mechanism 18 to shake significantly. The resilient recovering function of the recovering component 28 can cooperate with the positioning component 22 for rapidly dynamic adjustment, and the planar normal vector V1 of the flexure circuit board 24 and/or the hard substrate 26 can be kept in the Z-axis direction; the recovering component 28 and the base 20 can continuously contact against the flexure circuit board 24 without separation, and the foresaid continuous contact can avoid the global positioning system recognition results of the drone device 10 from being interfered with external high frequency signals. Generally, a pair of connectors 48 can be disposed between the flexure circuit boards 24, and used to electrically connect with related electronic component, and the hard substrate 26 can be disposed on the outside of the flexure circuit boards 24. The recovering component 28 can be preferably disposed adjacent to the positioning component 22, and used to absorb violent vibration of the circuit board connection mechanism 18 for keeping the planar normal vector V1 of the flexure circuit board 24 and/or the hard substrate 26 in the Z-axis direction. It should be mentioned that the hard substrate 26 and the connector 48 above the recovering component 28 are unnecessary elements, which means the recovering component 28 may directly contact against the flexure circuit board 24, or contact against an area of the hard substrate 26 that does not correspond to the connector 48 in some possible embodiments. If the circuit board connection mechanism 18 includes a plurality of positioning components 22, the recovering component 28 can be optionally disposed among the plurality of positioning components 22 for preferred balance; position of the recovering component 28 is not limited to the foresaid embodiment, and depends on the actual demand.

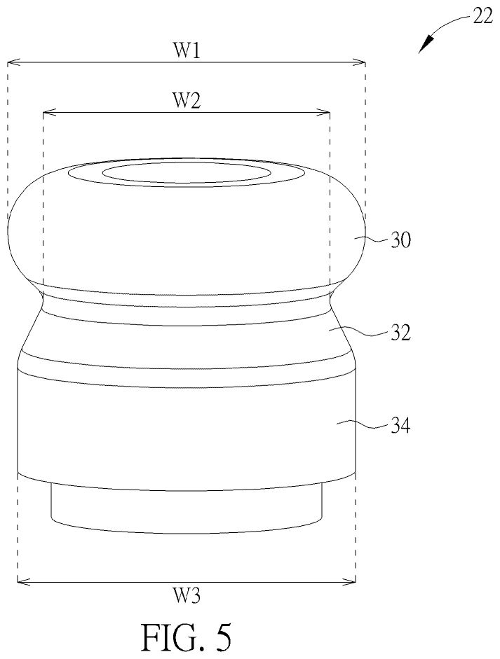

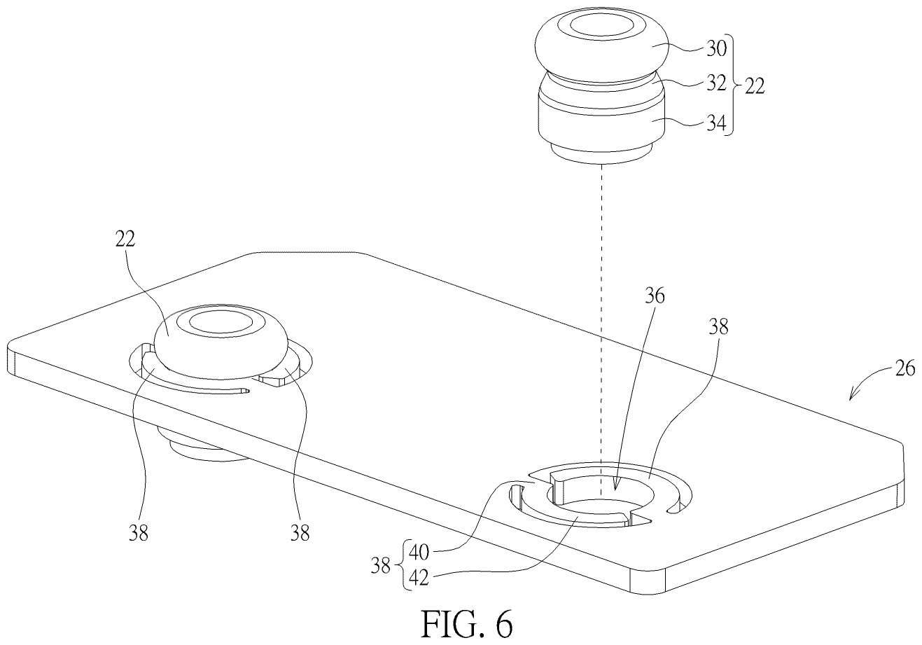

Please refer to FIG. 5 and FIG. 6. FIG. 5 is a diagram of the positioning component 22 according to the embodiment of the present invention. FIG. 6 is an assembly diagram of the positioning component 22 and the hard substrate 26 according to the embodiment of the present invention. The positioning component 22 can include a first section 30, a second section 32 and a third section 34 connected with each other in a sequence. The second section 32 can be located between the first section 30 and the third section 34. The third section 34 can be connected with the base 20. If the base 20 is the circuit board, the third section 34 can be disposed on the base 20 via surface mount technology; if the base 20 is the sheet metal, the third section 34 can be riveted on the base 20. The positioning component 22 can be connected with the base 20, the flexure circuit board 24 and the hard substrate 26, and further can be connected with the hard substrate 26 and a metallic element 46, as shown in FIG. 3.

A second structural width W2 of the second section 32 can be smaller than a first structural width W1 of the first section 30 and a third structural width W3 of the third section 34. The first structural width W1 can be greater than, equal to or smaller than the third structural width W3. An outline of the first section 30 can be designed as a curved structure and used to attach to an arm unit of the hard substrate 26. A segment structure can be set on a boundary between the second section 32 and the third section 34, and used to hold the arm unit of the hard substrate 26 for preventing the arm unit from falling. Besides, the hard substrate 26 can include a hole structure 36 and a supporting structure 38. An end of the supporting structure 38 can be connected with the wall of the hole structure 36, and the other end of the supporting structure 38 can be a free end, so the supporting structure 38 can be defined as the arm unit attached to the positioning component 22.

Moreover, the supporting structure 38 can include a plurality of arm units arranged in a symmetric manner. Each arm unit can include a connection portion 40 and an arc portion 42. Two opposite ends of the connection portion 40 can be respectively connected to the wall of the hole structure 36 and the end of the arc portion 42. The other end of the arc portion 42 can be adjacent to and spaced from another arm unit. As shown in FIG. 6, two arm units of the supporting structure 38 can form a restraint annular structure, and the restraint annular structure can be movably attached to the second section 32 of the positioning component 22. A radial dimension of the restraint annular structure can be smaller than the first structural width W1 and the third structural width W3, and greater than the second structural width W2. When the positioning component 22 abuts against the hard substrate 26 for attachment, the arm units of the supporting structure 38 can be outwardly pushed by the positioning component 22, and the first section 30 of the positioning component 22 can pass through the restraint annular structure; then, the arm units of the supporting structure 38 can be resiliently recovered to an initial state when aligning with the second section 32 of the positioning component 22, and the positioning component 22 can be fixed accordingly.

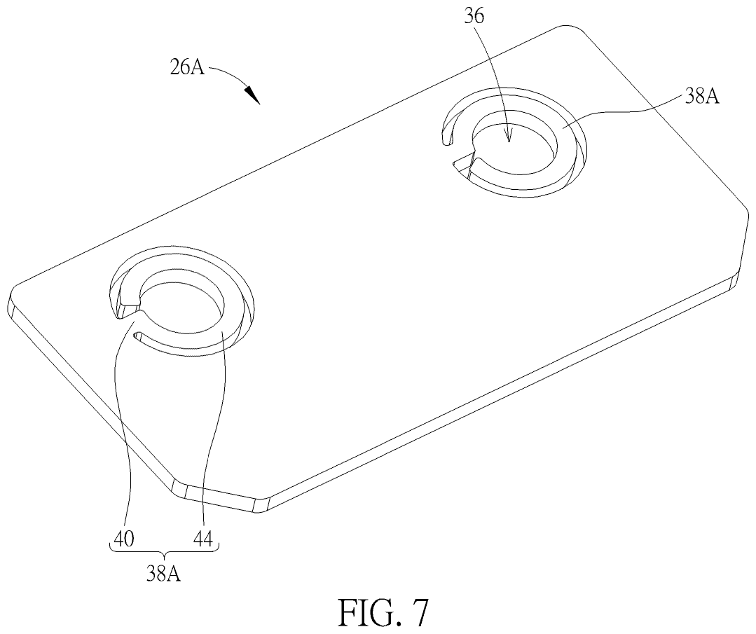

Please refer to FIG. 7. FIG. 7 is a diagram of the hard substrate 26A according to another embodiment of the present invention. In the embodiment, elements having the same numerals as ones of the foresaid embodiment can have the same structures and functions, and a detailed description is omitted herein for simplicity. The hard substrate 26A can include the hole structure 36 and the supporting structure 38A. The supporting structure 38A can further include the connection portion 40 and the C-type portion 44. Two opposite ends of the connection portion 40 can be respectively connected to the wall of the hole structure 36 and the C-type portion 44. The restraint annular structure formed by the supporting structure 38A can be attached to the second section 32 of the positioning component 22 via the resilient recovering feature of the arm unit.

In conclusion, the flexure circuit board can have a flexible function, and can be bent or folded for assembly, and therefore can meet the lightweight design requirement of the drone device because of light weight and thin thickness of the flexure circuit board. The present invention can provide the circuit board connection mechanism applied to the drone device, which can avoid an unexpected situation of the flexure circuit board, such as breakage or falling off, caused by instantaneous swing of the drone device during the flight. The circuit board connection mechanism of the present invention can utilize the positioning component with a middle section that is narrower than both end sections, and the hard substrate with the supporting structure having the resilient recovering features assembled with the flexure circuit board, to provide multi-axis dynamic adjustment in accordance with changes of the flight angle of the drone device, so as to effectively prevent the flexure circuit board from being damaged when the drone device is violently swung.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A circuit board connection mechanism comprising:
a base;
at least one positioning component disposed on the base, the positioning component comprising a first section, a second section and a third section connected to each other, the third section being connected to the base, a second structural width of the second section being smaller than a first structural width of the first section and a third structural width of the third section;
a flexure circuit board; and
a hard substrate where on the flexure circuit board is disposed, the hard substrate comprising a hole structure and a supporting structure, an end of the supporting structure being connected to a wall of the hole structure, a restraint annular structure formed by the supporting structure being movably attached to the second section, a radial dimension of the restraint annular structure being smaller than the first structural width and the third structural width and greater than the second structural width.

2. The circuit board connection mechanism of claim 1, wherein an outline of the first section of the positioning component is a curved structure, and a segment structure is formed on a boundary between the second section and the third section.

3. The circuit board connection mechanism of claim 1, wherein the supporting structure comprises a connection portion and a C-type portion, two opposite ends of the connection portion are respectively connected to the C-type portion and the wall of the hole structure.

4. The circuit board connection mechanism of claim 1, wherein the supporting structure comprises a plurality of arm units arranged in a symmetric manner, each arm unit comprises a connection portion and an arc portion, two opposite ends of the connection portion are respectively connected to an end of the arc portion and the wall of the hole structure, and the other end of the arc portion is adjacent to and spaced from another arm unit.

5. The circuit board connection mechanism of claim 1, wherein the circuit board connection mechanism further comprises a recovering component disposed between the hard substrate and the base.

6. The circuit board connection mechanism of claim 5, wherein a resiliently deformed direction of the recovering component is parallel to a planar normal vector of the hard substrate.

7. The circuit board connection mechanism of claim 5, wherein the recovering component is a helical compression spring or a S-type compression spring.

8. The circuit board connection mechanism of claim 5, wherein the circuit board connection mechanism further comprises a plurality of positioning components, and the recovering component is disposed among the plurality of positioning components.

9. A drone device, comprising:
a case;
a rotary wing mechanism disposed outside the case;
a driving module electrically connected to the rotary wing mechanism and disposed inside the case; and
a circuit board connection mechanism disposed inside the case, the circuit board connection mechanism comprising:
a base adapted to hold the driving module;
at least one positioning component disposed on the base, the positioning component comprising a first section, a second section and a third section connected to each other, the third section being connected to the base, a second structural width of the second section being smaller than a first structural width of the first section and a third structural width of the third section;
a flexure circuit board; and
a hard substrate where on the flexure circuit board is disposed, the hard substrate comprising a hole structure and a supporting structure, an end of the supporting structure being connected to a wall of the hole structure, a restraint annular structure formed by the supporting structure being movably attached to the second section, a radial dimension of the restraint annular structure being smaller than the first structural width and the third structural width and greater than the second structural width.

10. The circuit board connection mechanism of claim 9, wherein an outline of the first section of the positioning component is a curved structure, and a segment structure is formed on a boundary between the second section and the third section.

11. The circuit board connection mechanism of claim 9, wherein the supporting structure comprises a connection portion and a C-type portion, two opposite ends of the connection portion are respectively connected to the C-type portion and the wall of the hole structure.

12. The circuit board connection mechanism of claim 9, wherein the supporting structure comprises a plurality of arm units arranged in a symmetric manner, each arm unit comprises a connection portion and an arc portion, two opposite ends of the connection portion are respectively connected to an end of the arc portion and the wall of the hole structure, and the other end of the arc portion is adjacent to and spaced from another arm unit.

13. The circuit board connection mechanism of claim 9, wherein the circuit board connection mechanism further comprises a recovering component disposed between the hard substrate and the base.

14. The circuit board connection mechanism of claim 13, wherein a resiliently deformed direction of the recovering component is parallel to a planar normal vector of the hard substrate.

15. The circuit board connection mechanism of claim 13, wherein the recovering component is a helical compression spring or a S-type compression spring.

16. The circuit board connection mechanism of claim 13, wherein the circuit board connection mechanism further comprises a plurality of positioning components, and the recovering component is disposed among the plurality of positioning components.
